(19) United States
(12) Patent Application Publication
(10) Pub. No.: US 2021/0163819 A1
(43) Pub. Date: Jun. 3, 2021

(54) QUANTUM DOT LIGHT EMITTING DIODE LIGHT SOURCE AND LIGHT EMITTING DIODE

(71) Applicant: HUIZHOU CHINA STAR OPTOELECTRONICS TECHNOLOGY CO., LTD., GUANGDONG (CN)

(72) Inventors: Lianyan Song, Guangdong (CN); Yong Fan, Guangdong (CN)

(21) Appl. No.: 15/774,956

(22) PCT Filed: Apr. 9, 2018
(86) PCT No.: PCT/CN2018/082234

§ 371 Date: May 9, 2018

(30) Foreign Application Priority Data
Mar. 21, 2018 (CN) 201810232958.1

(51) Int. Cl. C09K 11/77; H01L 51/50

(52) U.S. Cl. CPC C09K 11/77346; B82Y 20/00; H01L 51/502

(57) ABSTRACT

A quantum dot light emitting diode (LED) light source and a LED are provided. The quantum dot LED light source includes a light combining layer and a blue light chip, wherein the light combining layer is disposed above the blue light chip, the light combining layer includes a fluorescent powder and quantum dots, and a chemical composition of the fluorescent powder is SrLiAl₃N₄:Eu²⁺.

### FIELD OF INVENTION

The disclosure relates to the field of display technology, and in particular to a quantum dot light emitting diode (LED) light source and a light emitting diode.

### BACKGROUND OF DISCLOSURE

In current liquid crystal display apparatuses, white light emitting diodes (LEDs) are generally used as backlight sources. In the most common white LEDs, a blue light emitting chip and a yellow florescent powder are used to emit light. However, LEDs using yellow florescent powder material in combination with a liquid crystal screen have lower color saturation and only 72% NTSC color gamut under the NTSE standard. In order to improve color gamuts of LEDs, color gamuts of LEDs are improved by changing the yellow florescent powder to the RG florescent powder, but this method can only increase LEDs to 90% NTSC color gamut. In order to meet high color gamut standards, quantum dot materials with narrow luminescence spectrums must be used, which are the easiest way to achieve a high color gamut and are also the most energy-efficient method.

Quantum dots are extremely tiny semiconductor nanocrystals that cannot be seen by the naked eye, and are particles less than 10 nanometers in size. In general, quantum dots are composed of zinc, cadmium, selenium, and sulfur atoms. Quantum dots are distinctively characterized by the fact that whenever quantum dots are stimulated by light and electricity, the quantum dots emit colored light. The color of the light is determined by the composition and size of the quantum dots. This characteristic allows the quantum dots to change the color of the light emitted from the light source.

Among quantum dots, the most studied materials are chalcogenide II-VI materials, ie, ZnS, ZnSe, CdS, CdSe, CdTe. The most notably material is CdSe, since it is tunable in the visible range of the spectrum. A reproducible method for the mass production of these materials has been developed from the “bottom up” technique, in which the “wet chemistry” process is used to atomically prepare particles (ie, from molecules to moieties, then to particles). However, cadmium and other limiting heavy metals used in conventional quantum dots are highly toxic elements and are a major concern in commercial applications. The inherent toxicity of cadmium-containing quantum dots makes them inapplicable to any application involving animals or humans For example, recent studies have shown that, without any protection, quantum dots made from cadmium chalcogenide semiconductor materials may cause cytotoxicity in biological environments. Specifically, oxidation or chemical erosion through various paths may result in formation of cadmium ions, which may be released into surrounding environments, on the surface of quantum dots. Therefore, there is currently an urgent need to develop a harmless light emitting diode with a high color gamut.

### SUMMARY OF INVENTION

The present disclosure provides a quantum dot light emitting diode (LED) light source and a light emitting diode (LED), so as to solve the problem that both a high color gamut of the existing light emitting diode and echo-friendly material cannot be achieved at the same time.

To achieve the above purpose, the technical solution provided by the present disclosure is as follows:

In accordance with an aspect of the present disclosure, a quantum dot light emitting diode (LED) light source is provided, including a light combining layer and a blue light chip, wherein the light combining layer is disposed above the blue light chip; the light combining layer includes a fluorescent powder and quantum dots, and a chemical composition of the fluorescent powder is SrLiAl₃N₄:Eu²⁺.

In accordance with an embodiment of the present disclosure, the light combining layer includes a quantum dot layer and a fluorescent layer.

In accordance with an embodiment of the present disclosure, the quantum dots are green quantum dots, the quantum dot layer includes the green quantum dots and a UV curable resin, and the green quantum dot are evenly dispersed in the UV curable resin.

In accordance with an embodiment of the present disclosure, the fluorescent powder is a red fluorescent powder, the fluorescent layer includes the red fluorescent powder and a silicone, and the red fluorescent powder is evenly dispersed in the silicone.

In accordance with an embodiment of the present disclosure, the quantum dot layer is disposed on an upper surface or a lower surface of the fluorescent layer.

In accordance with an embodiment of the present disclosure, the light combining layer includes quantum dots, a fluorescent powder and a silicone, and the quantum dots and the fluorescent powder are evenly dispersed in the silicone.

In accordance with an aspect of the present disclosure, a light emitting diode (LED) manufactured by using a quantum dot LED light source as described above is provided, including the quantum dot LED light source and a package;

wherein the package includes a metal lead frame on a bottom and a Wie epoxy molding compound (EMC) frame on a side, the metal lead frame and the EMC frame are assembled to form a concave central well, and the quantum dot LED light source is disposed in the central well;

wherein the LED further includes a first isolation layer, the first isolation layer completely fills gaps in the center well excluding the quantum dot LED light source, and the first isolation layer covers an upper surface of the EMC frame;

wherein the light combining layer is isolated from the blue light chip by the first isolation layer;

wherein the LED further includes a second isolation layer, the second isolation layer is disposed on an upper surface of the light combining layer, and the second isolation layer completely covers the light combining layer and the first isolation layer;

wherein material of the first isolation layer is one or more of silicon dioxide, aluminum nitride, silicon aluminum nitride, and aluminum oxide, and material of the second isolation layer is same as or different from the material of the first isolation layer.

In accordance with an aspect of the present disclosure, a light emitting diode (LED) manufactured by using a quantum dot LED light source as described above, including the quantum dot light emitting diode light source and a package;

wherein the package includes a metal lead frame on a bottom and a epoxy molding compound (EMC) frame on a side, the metal lead frame and the EMC frame are assembled to form a concave central well, and the quantum dot LED light source is disposed in the central well.

The advantage of the present disclosure is that a quantum dot LED light source and a light emitting diode (LED) are provided using a new type of cadmium-free florescent powder in place of the conventional nitride florescent powder. Not only is the content of cadmium element reduced, but also the LED with a high color gamut is realized, enhancing light emitting performance of the LED.

### BRIEF DESCRIPTION OF DRAWINGS

In order to more clearly illustrate the embodiments of the present disclosure or the technical solutions in prior arts, the following briefly introduces the accompanying drawings used in the embodiments. Obviously, the drawings in the following description merely show some of the embodiments of the present disclosure. As regards one of ordinary skill in the art, other drawings can be obtained in accordance with these accompanying drawings without making creative efforts.

FIG. 1 is a schematic structural diagram of a quantum dot light emitting diode (LED) light source in accordance with an embodiment of the present disclosure.

FIG. 2 is a schematic structural diagram of another quantum dot LED light source in accordance with an embodiment of the present disclosure.

FIG. 3 is a schematic structural diagram of yet another quantum dot LED light source in accordance with an embodiment of the present disclosure.

FIG. 4 is a schematic structural diagram of a LED in accordance with an embodiment of the present disclosure.

FIG. 5 is an excitation spectrum and an emission spectrum of a red florescent powder in accordance with an embodiment of the present disclosure.

FIG. 6 is an emission spectrum of a green quantum dot in accordance with an embodiment of the present disclosure.

### DETAILED DESCRIPTION OF PREFERRED EMBODIMENTS

The following description of the embodiments with reference to the accompanying drawings is used to illustrate particular embodiments of the present disclosure. The directional terms referred in the present disclosure, such as “upper”, “lower”, “front”, “back”, “left”, “right”, “inner”, “outer”, “side surface”, etc. are only directions with regard to the accompanying drawings. Therefore, the directional terms used for describing and illustrating the present disclosure are not intended to limit the present disclosure.

The present disclosure provides a quantum dot LED light source and a light emitting diode for the problem that both a high color gamut of the existing light emitting diode and echo-friendly material cannot be achieved at the same time. This embodiment improves this defect.

The following further describes the present disclosure with reference to the accompanying drawings and specific embodiments:

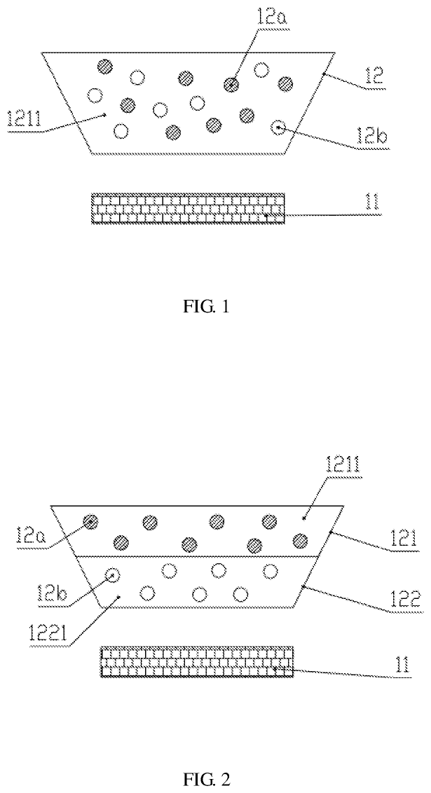

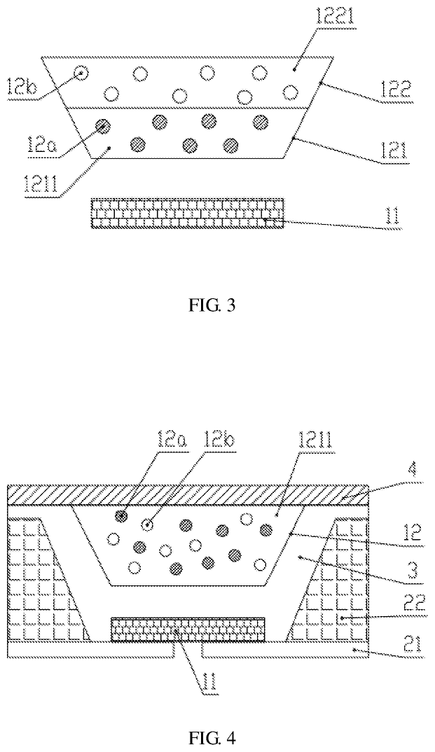

FIG. 1 is a schematic structural diagram of a quantum dot light emitting diode (LED) light source in accordance with an embodiment of the present disclosure. FIG. 2 is a schematic structural diagram of another quantum dot LED light source in accordance with an embodiment of the present disclosure. FIG. 3 is a schematic structural diagram of yet another quantum dot LED light source in accordance with an embodiment of the present disclosure.

As shown in FIG. 1, the present disclosure provides a quantum dot light emitting diode (LED) light source 1 including a light combining layer 12 and a blue light chip 11, wherein the light combining layer 12 is disposed above the blue light chip 11.

The light combining layer 12 includes a florescent powder 12a and quantum dots 12b. A chemical composition of the florescent powder 12a is SrLiAl₃N₄:Eu²⁺.

In the field of display technology, white LEDs are generally used as a backlight in a display apparatus. In the present disclosure, the color conversion mechanism of the light emitted from the LED is to combine the blue chip 11 with the red florescent powder and the green quantum dots to prepare a quantum point white LED, in which a part of blue light emitted from the blue chip 11 is absorbed by the green quantum dots to be converted to green light, and a part of the blue light emitted from the blue chip 11 is absorbed by the red florescent powder to be converted to red light. Utilizing the principle of red, green and blue colors, the green light, the red light and the remaining blue light are combined to form white light.

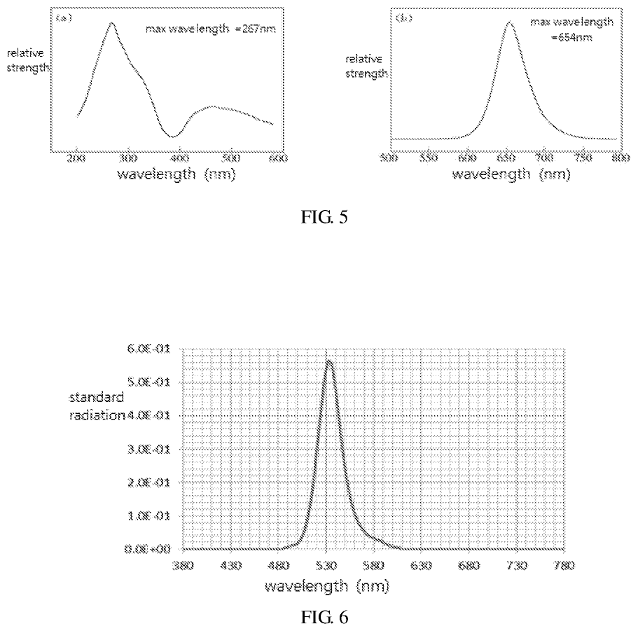

Furthermore, the chemical composition of the florescent powder 12a is: SrLiAl₃N₄:Eu²⁺. As shown in FIG. 5 and FIG. 6, the excitation spectrum of the florescent powder 12a exhibits a double-peak band as the excitation band ranges from 200 nm to 600 nm. There are excitation peaks at 267 nm and 474 nm, respectively. However, the florescent powder 12a has only one emission peak band at 654 nm, which is longer than the peak wavelength of the existing nitride red florescent powder. The half-height width of the pulse of the florescent powder 12a is only 51 nm, which is far less than the half-height width of the pulse of the existing nitride-based florescent powder, making the achievement of a high color gamut of the light emitting diode easier.

Through simulation tests, it has been proved that using the nitride-based florescent powder together with the quantum dots for light emission, only 92.8% NTSC color gamut can be achieved. However, using the florescent powder 12a in the present disclosure with the same quantum dot for light emission, 105.9% NTSC color gamut of the LED can be achieved, and both 96.5% DCI-P3 gamut and 83.4% BT2020 gamut are achieved. It has been found through research that the florescent powder 12a has higher thermal stability and quantum efficiency.

In one embodiment, the light combining layer 12 includes a quantum dot layer 122 and a florescent layer 121.

Furthermore, the quantum dots 12b are green quantum dots, and the quantum dot layer 122 includes the green quantum dots and a UV curable resin 1221, and the green quantum dots are evenly dispersed in the UV curable resin 1221.

The florescent powder 12a is a red florescent powder. The florescent layer 121 includes the red florescent powder and a silicone 1211. The red florescent powder is evenly dispersed in the silicone 1211.

The silicone 1211 may also be a fluoride-containing phosphorescent silicone.

The quantum dot layer 122 is disposed on an upper surface or a lower surface of the fluorescent layer 121. The position is not ragarded as a limitation herein.

It should be noted that the florescent powder 12a and the quantum dots 12b may be provided separately, or the florescent powder 12a and the quantum dots 12b may be evenly mixed and packaged together.

As shown in FIG. 1, the light combining layer 12 includes the quantum dots 12b, the florescent powder 12a, and the silicone 1211. The quantum dots 12b and the florescent powder 12a are evenly dispersed in the silicone 1211.

According to another aspect of the present disclosure, a light emitting diode (LED) is also provided. The LED is prepared using the quantum dot LED light source 1. The LED includes the quantum dot LED light source 1 and a package 2.

As shown in FIG. 4, the package 2 includes a metal lead frame 21 on the bottom and a Wie epoxy molding compound (EMC) frame 22 on the sides. The metal lead frame 21 and the EMC frame 22 are assembled to form a concave central well, and the quantum dot LED light source is disposed in the central well.

In the present disclosure, the use of the silicone 1211 alone cannot achieve the condition isolating the quantum dot LED light source 1 from water and oxygen. Generally, the oxygen permeability of the water-impermeable oxygen-permeable silicone ranges from 120 ml per square meter per day to 350 ml per square meter per day. In fact, the quantum dot 12b requires an isolating condition of 0.1 ml per square meter per day. Therefore, in the present disclosure, the LED further includes a first isolation layer 3, and the first isolation layer 3 completely fills gaps in the center well excluding the quantum dot LED light source 1, and the first isolation layer 3 covers an upper surface of the EMC frame 22.

The light combining layer 12 is isolated from the blue chip 11 by the first isolation layer 3.

Furthermore, the LED further includes a second isolation layer 4, the second isolation layer 4 is disposed on an upper surface of the light combining layer 12, and the second isolation layer 4 completely covers the light combining layer 12 and the first isolation layer 3. Such an arrangement not only increases the heat dissipation of the quantum dot LED light source 11, but also greatly increases the isolation from water and oxygen, effectively protecting the florescent powder 12a and the quantum dots 12b from corrosion.

Material of the first isolation layer 3 is one or more of silicon dioxide, aluminum nitride, silicon aluminum nitride, and aluminum oxide, and material of the second isolation layer 4 is same as or different from material of the first isolation layer 3. The material of the first isolation layer 3 and the material of the second isolation layer 4 are both inorganic materials.

In this embodiment, the principle of the quantum dot LED light source of the LED is the same as the principle of the quantum dot LED light source. The details are referred to the principle of the quantum dot LED light source, and are not redundantly described herein.

The present disclosure provides a quantum dot LED light source and a LED, using a new type of cadmium-free florescent powder in place of the conventional nitride florescent powder. Not only is the content of cadmium element reduced, but also the LED with a high color gamut is realized, enhancing light emitting performance of the LED

In summary, although the preferable embodiments of the present disclosure have been disclosed above, the embodiments are not intended to limit the present disclosure. A person of ordinary skill in the art, without departing from the spirit and scope of the present disclosure, can make various modifications and variations. Therefore, the scope of the disclosure is defined in the claims.

What is claimed is:

1. A quantum dot light emitting diode (LED) light source, comprising:
a light combining layer and a blue light chip, wherein the light combining layer is disposed above the blue light chip; the light combining layer includes a fluorescent powder and quantum dots, and a chemical composition of the fluorescent powder is SrLiAl₃N₄:Eu²⁺.

2. The quantum dot LED light source as claimed in claim 1, wherein the light combining layer includes a quantum dot layer and a fluorescent layer.

3. The quantum dot LED light source as claimed in claim 2, wherein the quantum dots are green quantum dots, the quantum dot layer includes the green quantum dots and a UV curable resin, and the green quantum dot are evenly dispersed in the UV curable resin.

4. The quantum dot LED light source as claimed in claim 2, wherein the fluorescent powder is a red fluorescent powder, the fluorescent layer includes the red fluorescent powder and a silicone, and the red fluorescent powder is evenly dispersed in the silicone.

5. The quantum dot LED light source as claimed in claim 2, wherein the quantum dot layer is disposed on an upper surface or a lower surface of the fluorescent layer.

6. The quantum dot LED light source as claimed in claim 1, wherein the light combining layer includes quantum dots, a fluorescent powder and a silicone, and the quantum dots and the fluorescent powder are evenly dispersed in the silicone.

7. A light emitting diode (LED) manufactured by using a quantum dot LED light source as claimed in claim 1, comprising the quantum dot LED light source and a package;
wherein the package includes a metal lead frame on a bottom and a Wie epoxy molding compound (EMC) frame on a side, the metal lead frame and the EMC frame are assembled to form a concave central well, and the quantum dot LED light source is disposed in the central well;
wherein the LED further includes a first isolation layer, the first isolation layer completely fills gaps in the center well excluding the quantum dot LED light source, and the first isolation layer covers an upper surface of the EMC frame;
wherein the light combining layer is isolated from the blue light chip by the first isolation layer;
wherein the LED further includes a second isolation layer, the second isolation layer is disposed on an upper surface of the light combining layer, and the second isolation layer completely covers the light combining layer and the first isolation layer;
wherein material of the first isolation layer is one or more of silicon dioxide, aluminum nitride, silicon aluminum nitride, and aluminum oxide, and material of the second isolation layer is same as or different from the material of the first isolation layer.

8. A light emitting diode (LED) manufactured by using a quantum dot LED light source as claimed in claim 1, comprising the quantum dot light emitting diode light source and a package;
wherein the package includes a metal lead frame at a bottom and a epoxy molding compound (EMC) frame at a side, the metal lead frame and the EMC frame are assembled to form a concave central well, and the quantum dot LED light source is disposed in the central well.
